(19) United States
(12) Patent Application Publication
(10) Pub. No.: US 2012/0146136 A1
(43) Pub. Date: Jun. 14, 2012

(54) VERTICAL SEMICONDUCTOR DEVICE AND METHOD OF MANUFACTURING THE SAME

(75) Inventor: Jin Won PARK, Seongnam (KR)

(73) Assignee: Hynix Semiconductor Inc., Gyeonggi-do (KR)

(21) Appl. No.: 13/021,143

(22) Filed: Feb. 4, 2011

(30) Foreign Application Priority Data
Dec. 14, 2010 (KR) 10-2010-0127638

(51) Int. Cl. H01L 29/78; H01L 21/336

(52) U.S. Cl. 257/331; 257/333; 438/270; 257/E29.262; 257/E21.41

(57) ABSTRACT

A vertical semiconductor device includes a first pillar and a second pillar, a first bit line contact formed at a lower portion of a first sidewall of the first pillar, a second bit line contact formed at a lower portion of a second sidewall of the second pillar which face the first sidewall of the first pillar, a bit line commonly connected to the first bit line contact and the second bit line contact, and a gate formed at both sides of the first pillar and the second pillar to be crossed with the bit line.

### CROSS-REFERENCES TO RELATED APPLICATION

The priority of Korean patent application No. 10-2010-0127638 filed on Dec. 14, 2010, the disclosure of which is hereby incorporated in its entirety by reference, is claimed.

### BACKGROUND OF THE INVENTION

1. Technical Field

The present invention relates to a vertical semiconductor device and a method of manufacturing the same, and more particularly, to a vertical semiconductor device capable of simplifying a fabrication process of a vertical cell transistor by forming bit line contacts at both sides of a buried bit line to share the buried bit line with vertical cells at both sides of the buried bit line in a 4F² vertical cell structure, and a method of manufacturing the same.

2. Related Art

As the degree of integration of semiconductor devices increases, dynamic random access memory (DRAM) devices of below 40 nm have been demanded so as to improve device integration. However, it is difficult to scale down planar or recess gate transistors below 40 nm, which are used in 8F² (F: minimum feature size) or 6F² cell architecture. Therefore, DRAM devices having a 4F² cell architecture capable of improving integration by one and a half to two times in the same scaling has been demanded.

To constitute a 4F² cell architecture, a DRAM fabrication process has to capable of forming a source unit and a drain unit of a cell transistor in 1F², the source unit being a capacitor forming region in which charges are stored and the drain unit being a region where charges drain into a bit line. Thus, recent research efforts have focused on a vertical cell transistor structure which comprises a source unit and a drain unit in 1F². The vertical cell transistor structure has a structure where a source region and a drain region of a transistor which drives a unit cell are arranged vertically, and the transistor operates by a vertical pillar type channel. That is, compared with the source region and the drain region formed in a planar shape in 8F², a vertical cell transistor structure in which the source region and the drain region are arranged vertically is capable of fabricating a cell transistor driving in 4F².

As shown in FIG. 1, a one side contact (OSC) is formed at one sidewall of a buried bit line (BBL) to connect the buried bit line BBL with a bit line junction region in a lower portion of a pillar in the 4F² cell architecture.

However, it is very difficult to form the bit line contact OSC only at the one sidewall of the buried bit line BBL and it is difficult to stably form the bit line contact OSC asymmetrically.

### SUMMARY

The present invention is to provide a method capable of stably manufacturing a vertical semiconductor device with ease by improving its structure.

According to one aspect of an exemplary embodiment, a semiconductor device includes a first pillar and a second pillar, a first bit line contact formed at a lower portion of a first sidewall of the first pillar, a second bit line contact formed at a lower portion of a first sidewall of the second pillar which faces the first sidewall of the first pillar, a bit line commonly connected to the first bit line contact and the second bit line contact, a first gate formed over a second sidewall of the first pillar and over the second sidewall of the second pillar, and a second gate formed over a third sidewall of the first pillar and over a third sidewall of the second pillar, wherein the first and second gates extend cross the bit line, respectively.

The vertical semiconductor device may further include a gate oxide layer formed to have different thicknesses on both sides of the first pillar and the second pillar.

The vertical semiconductor device may further include a first gate oxide layer formed between the second sidewall of the first pillar and the first gate and a second gate oxide layer formed between the third sidewall of the first pillar and the second gate, wherein the first gate oxide layer has a thickness sufficient to enable a channel to be formed in the first pillar under the first gate oxide layer, and wherein the second gate oxide layer has a thickness that is insufficient to form a channel in the first pillar under the second gate oxide layer.

The vertical semiconductor device may further include a third gate oxide layer formed between the second pillar and a fourth gate oxide layer formed between the third sidewall of the second pillar and the second gate, wherein the third gate oxide layer has a thickness insufficient to form a channel in the second pillar under the third gate oxide layer and wherein the fourth gate oxide layer has a thickness sufficient to enable a channel be formed in the second pillar under the fourth gate oxide layer.

The vertical semiconductor device may further include a first dummy bit line formed over a fourth sidewall of the first pillar and a second dummy bit line formed over a fourth sidewall of the second pillar, wherein each of the first and the second dummy bit lines is parallel to the bit line.

According to another aspect of another exemplary embodiment, a vertical semiconductor device includes a first pillar adjacent to a second pillar, a gate shared with the first pillar and the second pillar, and a bit line commonly coupled to the first pillar and the second pillar and formed between the first pillar and the second pillar, wherein the bit line crosses the gate.

The vertical semiconductor device may further include bit line contacts formed on both sidewalls of the bit line and connected to bit line junction regions at lower portions of the first pillar and the second pillar.

The gate may include a first gate formed on one sides of the first pillar and the second pillar and a second gate formed on the other sides of the first pillar and the second pillar parallel to the first gate.

The vertical semiconductor device may further include a gate oxide layer formed to have different thicknesses on both sides of the first pillar and the second pillar.

The gate oxide layer may be formed so that a portion of the gate oxide layer between the first gate and the second pillar has a thicker thickness than a portion of the gate oxide layer between the first gate and the first pillar and a portion of the gate oxide layer between the second gate and the first pillar has a thicker thickness than a portion of the gate oxide layer between the second gate and the second pillar.

The vertical semiconductor device may further include dummy bit lines formed on outer sidewalls of the first pillar and the second pillar parallel to the bit line.

According to another aspect of another exemplary embodiment, a method of manufacturing a vertical semiconductor device includes forming a first pillar and a second pillar adjacent to the first pillar by etching a semiconductor substrate, forming a first gate coupled to the first pillar, forming a second gate coupled to the second pillar, the second gate being in parallel to the first gate and forming a bit line commonly coupled to the first pillar and the second pillar and formed between the first pillar and the second pillar, wherein the bit line crosses each of the first and the second gates.

The forming a bit line may include forming a plurality of line type pillars by etching the semiconductor substrate, forming a plurality of bit line junction regions in lower portions of sidewalls of the pillars which face each other, and forming a conduction layer between the facing sidewalls of the pillars to be commonly coupled to the bit line junction regions in the facing sidewalls.

The forming bit line junction regions may include forming an oxide layer over the lower portions of the facing sidewalls, forming a nitride layer over exposed upper portions of the facing sidewalls above the oxide layer, partially removing an upper portion of the oxide layer to expose the semiconductor substrate, and diffusing impurities into the exposed semiconductor substrate.

The method may further include, before the diffusing impurities, forming a diffusion controlling layer configured to control a diffusion depth into the exposed portions of the pillars.

The forming a gate may include forming a first gate oxide layer between the first pillar and the first gate, forming a second gate oxide layer between the first pillar and the second gate, forming a third gate oxide layer between the second pillar and the first gate, forming a fourth gate oxide layer between the second pillar and the second gate, and forming a conduction layer over each of the first, the second, the third, and the fourth gate oxide layers, wherein the first gate oxide layer is different in thickness from a second gate oxide layer formed between the first pillar and the second gate, and wherein the third gate oxide layer is different in thicknesses from the fourth gate oxide layer. At this time, the forming a gate oxide layer having different thicknesses may include forming a first gate oxide layer on the both side walls of the first pillar and the second pillar, removing a portion of the first gate oxide layer on a one side of the first pillar and the other side of the second pillar, and forming a second gate oxide layer on the both sidewalls of the first pillar and the second pillar.

According to another aspect of another exemplary embodiment, a vertical semiconductor device includes a genuine bit line and a dummy bit line arranged in an alternating manner and extending parallel to each other, a first gate line and a second gate line arranged in an alternating manner and extending parallel to each other, the first gate line and the second gate line extending across the genuine and the dummy bit lines, an even pillar coupled to the genuine bit line and the first gate line, and an odd pillar coupled to the genuine bit line and the second gate line.

The genuine bit line may commonly couple to the even pillar and an odd pillar which is adjacent to the even pillar.

The even pillar may be insulated from the dummy bit line and from the second gate line, and wherein the odd pillar is insulated from the dummy bit line and from the first gate line.

The even pillar may include a first sidewall coupled to the genuine bit line, a second sidewall coupled to the first gate line, a third sidewall formed over the dummy line without being coupled to the dummy line, and a fourth sidewall formed over the second gate line without being coupled to the second gate line.

The odd pillar may include a first sidewall coupled to the genuine bit line, a second sidewall coupled to the second gate line, a third sidewall formed over the dummy line without being coupled to the dummy line, and a fourth sidewall formed over the first gate line without being coupled to the second gate line.

The even pillar is located at an intersection of the genuine bit line and the first gate line, and wherein the odd pillar is located at an intersection of the genuine bit line and the second gate line.

According to another aspect of another exemplary embodiment, a method of manufacturing a vertical semiconductor device includes forming a genuine bit line and a dummy bit line arranged in an alternating manner and extending parallel to each other, forming a first gate line and a second gate line arranged in an alternating manner and extending parallel to each other, the first gate line and the second gate line extending across the genuine and the dummy bit lines, forming an even pillar coupled to the genuine bit line and the first gate line, and forming an odd pillar coupled to the genuine bit line and the second gate line.

According to a vertical semiconductor device and a method of manufacturing the same of the present invention, bit line contacts are formed at both sides of a buried bit line so that vertical cells at both sides of the buried bit line share the buried bit line. Therefore, the fabrication process of a vertical cell transistor can be simplified to stably fabricate the vertical semiconductor device with ease.

These and other features, aspects, and embodiments are described below in the section entitled “DESCRIPTION OF EXEMPLARY EMBODIMENT”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a diagram illustrating a 4F² cell architecture in which a bit line contact is formed at one side of a buried bit line in the related art;

FIG. 2 is a perspective view illustrating a configuration of a vertical semiconductor device having a 4F² cell architecture according to an exemplary embodiment of the present invention;

FIG. 3 is a plan view illustrating a configuration of a vertical semiconductor device having a 4F² cell architecture according to an exemplary embodiment of the present invention; and

FIGS. 4 to 10 are cross-sectional views illustrating a method of manufacturing a vertical semiconductor device according to an exemplary embodiment of the present invention.

### DESCRIPTION OF EXEMPLARY EMBODIMENT

Exemplary embodiments are described herein with reference to cross-sectional illustrations that are schematic illustrations of exemplary embodiments and intermediate structures. As such, variations from the shapes of the illustrations as a result, for example, of manufacturing techniques and/or tolerances, are to be expected. Thus, exemplary embodiments should not be construed as limited to the particular shapes of regions illustrated therein but may include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

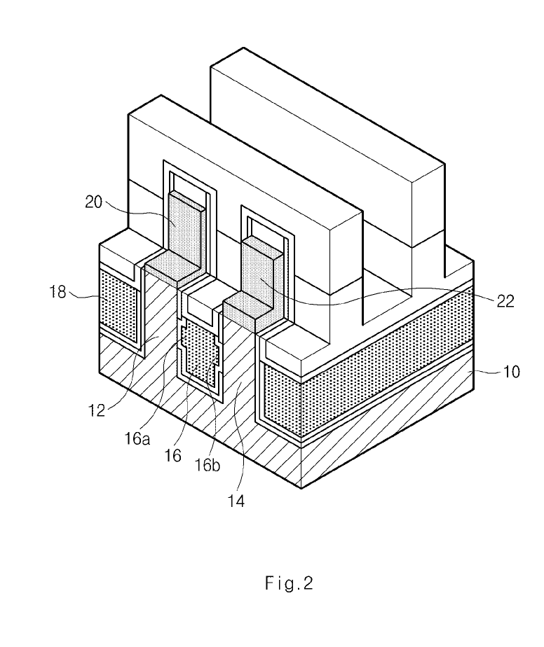

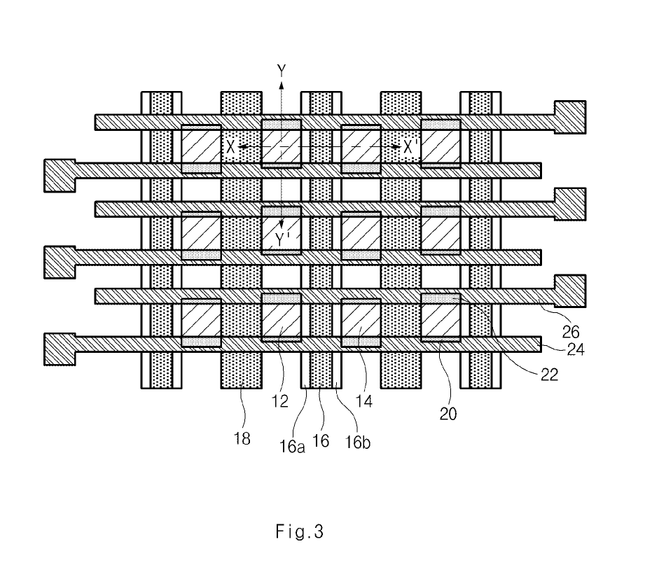

FIG. 2 is a perspective view illustrating a configuration of a vertical semiconductor device having a 4F² cell architecture according to an exemplary embodiment of the present invention and FIG. 3 is a plan view illustrating a vertical semiconductor device having a 4F² cell architecture according to an exemplary embodiment of the present invention.

Referring to FIGS. 2 and 3, in a vertical semiconductor device according to an exemplary embodiment, pillars 12 and 14 are formed protruded from a semiconductor substrate 10 by etching the semiconductor substrate 10. A buried bit line 16 is formed between the adjacent pillars 12 and 14 to be commonly connected to the pillars 12 and 14, and dummy buried bit lines 18 are formed on opposite sides of the pillars 12 and 14.

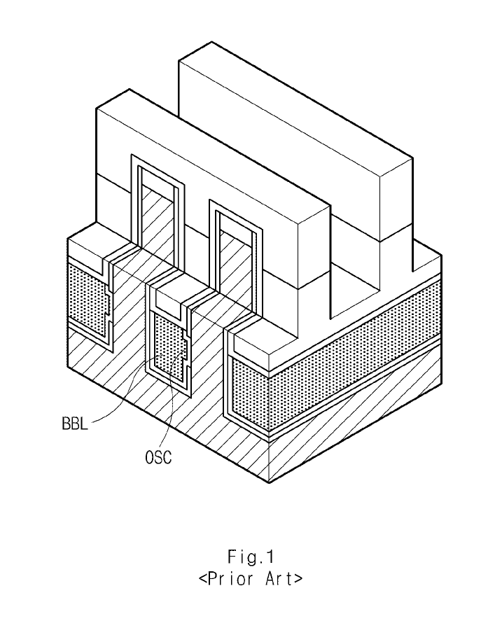

That is, bit line contacts 16a and 16b are formed on both sides of the buried bit line 16 formed between the adjacent pillars 12 and 14 so that the bit line 16 is commonly connected to bit line junction regions of the adjacent two pillars 12 and 14 via the bit line contact regions 16a and 16b. Therefore, although conventional vertical semiconductor devices have a one side contact (OSC) structure in which the bit line contact OSC is formed only on one sidewall of the buried bit line BBL as illustrated in FIG. 1, a vertical semiconductor device according to an exemplary embodiment has a both side contact (BSC) structure in which the bit line contacts 16a and 16b are formed on the both sides of the buried bit line 16.

In order to facilitate this structure, dummy buried bit lines 18 are formed on opposite sides of the two pillars 12 and 14 so that the dummy buried bit lines 18 are not connected to either of the two pillars 12 and 14. That is, in the exemplary embodiment, the buried bit line 16 is electrically or magnetically or electromagnetically coupled to pillars (vertical cells) located on both sides of the buried bit line 16, but the dummy buried bit line 18 is not coupled to any pillars electrically, magnetically or electromagnetically.

Vertical gates 24 and 26 are formed at both sides of the pillars 12 and 14 over the buried bit line 16 and the dummy buried bit lines 18 to be crossed with the buried bit line 16 and the dummy buried bit line 18.

The vertical gates 24 and 26 formed at both sides of the pillars 12 and 14 serve as separate word lines, so that each pillar 12 and 14 is respectively controlled by the vertical gates 24 and 26 to form channels therein. For instance, a first channel may be formed in the pillar 12 with the vertical gate 24, and a second channel may be formed in the pillar 14 with the vertical gate 26. However, in this embodiment, the pillar 12 and the vertical gate 26 do not form a channel, and the pillar 14 and the vertical gate 24 do not form a channel.

Accordingly, out of a series of sequentially numbered pillars formed along the vertical gate, for example, odd pillars are controlled by the vertical gate 24 to form channels and even pillars are controlled by the vertical gate 26 to form channels.

In the exemplary embodiment, the reason that the different vertical gates 24 and 26 are formed at both sides of the pillars 12 and 14 but are not configured to simultaneously form channels in both pillars 12 and 14 is because the buried bit line 16 is shared with both of the pillars 12 and 14.

Thus, in order to form the channels in adjacent pillars 12 and 14 with the vertical gates 24 and 26, gate oxide layers 20 and 22 are formed to have different thicknesses between the pillars 12 and 14 and the vertical gates 24 and 26.

For example, the gate oxide layer 20 having a lower thickness is formed between the pillar 12 and the vertical gate 24 so that a channel is formed in the pillar 12 by a power voltage applied to the vertical gate 24. Alternatively, the gate oxide layer 22 having a higher thickness is formed between the pillar 12 and the vertical gate 26 so that a channel is not formed in the pillar 12 by a power voltage applied to the vertical gate 26. The gate oxide layer 20 between the pillar 12 and the vertical gate 24 may be formed to a thickness of 55 to 60 Å, and the gate oxide layer 22 between the pillar 12 and the vertical gate 26 may be formed to a thickness of 80 to 150 Å.

On the other hand, the gate oxide layers 20 and 22 between the pillar 14 and the vertical gates 24 and 26 are formed in reverse of the configuration described above.

The gate oxide layer 20 between the pillar 14 and the vertical gate 26 is thinly formed to form a channel in the pillar 14 when a power voltage is applied to the vertical gate 26. The gate oxide layer 22 between the pillar 14 and the vertical gate 24 is thickly formed to not form a channel in the pillar 14 when a power voltage is applied to the vertical voltage 24.

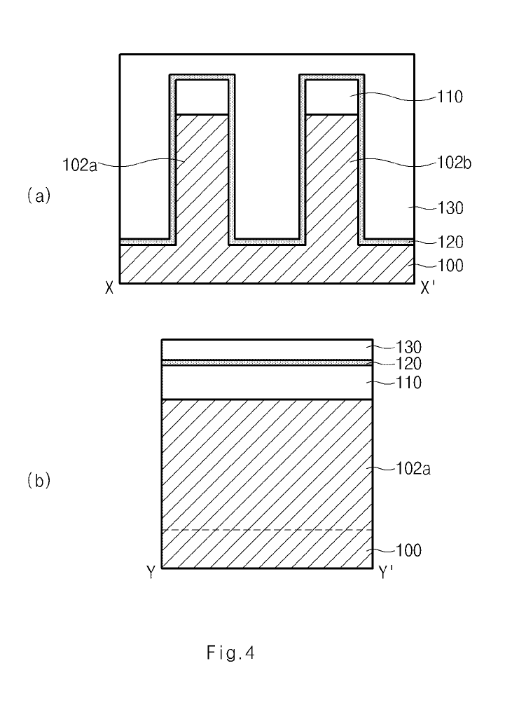

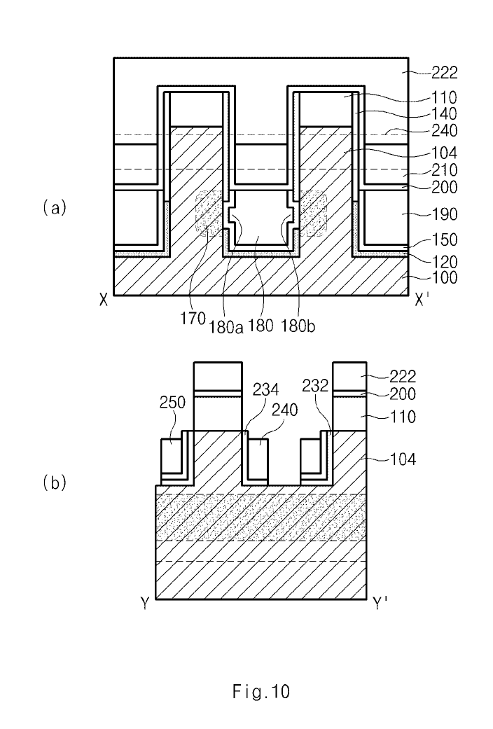

FIGS. 4 and 10 are cross-sectional views illustrating a method of manufacturing a vertical semiconductor device according to an exemplary embodiment of the present invention. In FIGS. 4 to 10, (a) is a cross-sectional view taken along a line X-X′ of FIG. 3 and (b) is a cross-sectional view taken along a line Y-Y′ of FIG. 3.

Referring to FIG. 4, a hard mask pattern 110 defines a region in which a bit line is to be formed on a semiconductor substrate 100. The hard mask pattern 110 may include a hard mask material layer and an antireflection layer. The hard mask material layer may include a stack layer of a nitride layer and amorphous carbon layer (ACL) and the antireflection layer may include a silicon oxynitride (SiON) layer.

The semiconductor substrate 100 is etched to a predetermined depth using the hard mask pattern 110 as an etching mask to form line type pillars 102a and 102b.

Next, an insulating layer 120 is formed on the semiconductor substrate 100 including the pillars 102a and 102b ad and a conduction layer 130 is formed on the insulating layer 130 to be filled between the pillars 102a and 102b. At this time, the insulating layer 120 may include an oxide layer such as tetraethyl orthosilicate formed by a low pressure chemical vapor deposition process (LPTEOS), and the conduction layer may include a polysilicon layer.

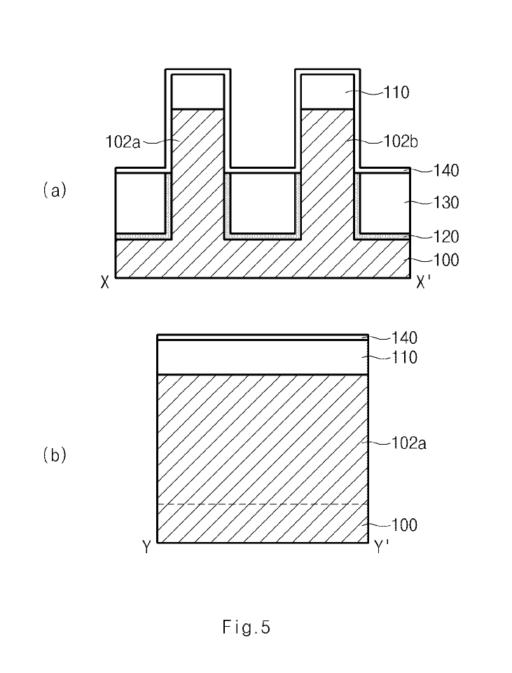

Referring to FIG. 5, the conduction layer 130 is etched back to a predetermined depth to remain at a lower portion of a trench between the pillars 102a and 102b. At this time, when the conduction layer is etched back, the portion of the insulating layer 120 which is formed on sidewalls of the pillars 102a and 102b above the remaining conduction layer 130 may be also removed. The amount of the conduction layer 130 that is etched may depend on a position of a bit line contact (not shown) which is to be formed in the following process.

Next, an insulating layer 140 is formed on the whole surface of the semiconductor substrate 100. The insulating layer 140 may include a nitride layer.

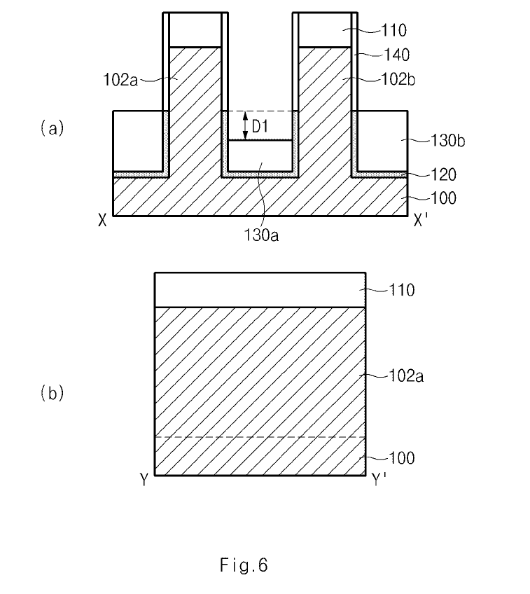

Referring to FIG. 6, the insulating layer 140 is etched back to remain as a spacer on both sidewalls of the pillars 102a and 102b and to expose the upper surfaces of the hard mask pattern 110 and the conduction layers 130a and 130b.

Next, a portion of the conduction layer 130a is further etched by a depth D1 to expose an upper portion of the insulating layer 120 without etching the conduction layer 130b. That is, only the portion of the conductive layer 130a between facing sidewalls of the pillars 102a and 102b is further etched by a depth D1, and conduction layer 130b (the conduction layer reserved to be a dummy buried bit line) formed on opposite sidewalls of the pillars 102a and 102b is not etched.

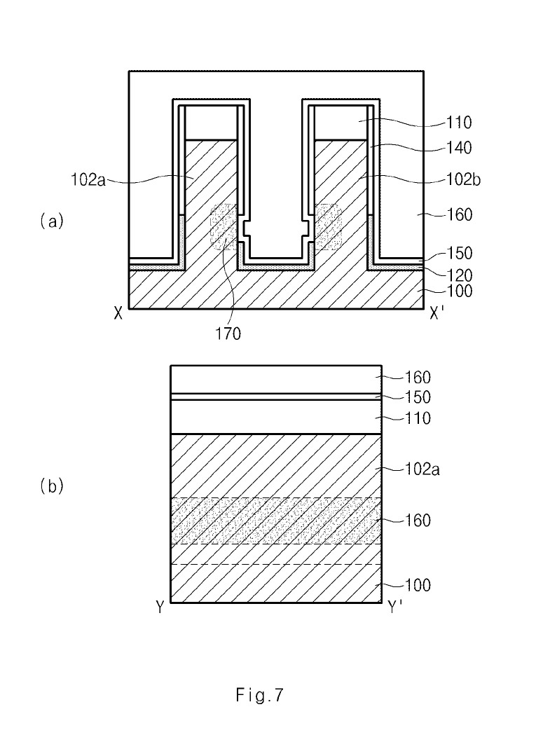

Referring to FIG. 7, the exposed portion of the insulating layer 120 is removed to form bit line contact regions at lower portions of the facing sidewalls of the pillars 102a and 102b.

Next, the conduction layers 130a and 130b are removed and a barrier layer 150 for diffusion prevention is formed on the whole surface of the semiconductor substrate 100. The barrier layer 150 may include a Ti/TiN layer. The barrier layer 150 prevents a bit line junction region formed in a subsequent process from being deeply formed in each pillar 102a and 102b, so that a body floating effect is prevented from occurring.

A conduction layer 160 is formed to fill the space between the pillars 102a and 102b. The conduction layer 160 may include a doped polysilicon layer. For example, the conduction layer 160 may include a polysilicon layer doped with phosphor as a dopant.

Next, an annealing process is performed on the conduction layer 160 so that impurities of the conduction layer 160 are diffused into the pillars 102a and 102b to form bit line junction regions 170 in lower portions of the pillars 102a and 102b.

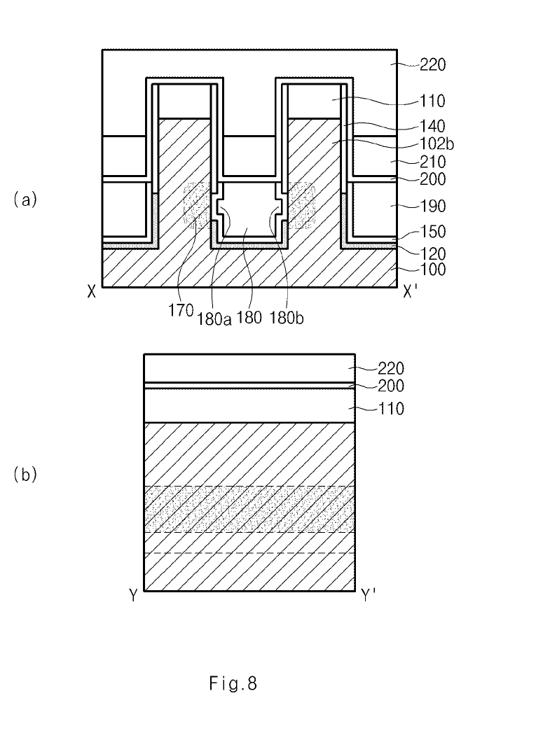

Referring to FIG. 8, the conduction layer 160 is removed by an etch back process. A conduction layer for a bit line (not shown) is formed to fill between the pillars 102a and 102b on the whole surface of the semiconductor substrate 100, and the conduction layer and the barrier layer 150 are removed by a predetermined depth to form a buried bit line 180 and a dummy buried bit line 190. At this time, bit line contacts 180a and 180b are formed on both sides of the buried bit line 180 so that the buried bit line 180 is commonly connected to bit line junction regions 170 in the lower portions of the facing sidewalls of the pillars 102a and 102b. On the other hand, the dummy buried bit line 190 is not connected to any bit line junction region. The conduction layer for a bit line may include a metal layer. The metal layer may include tungsten.

Next, a spacer insulating layer 200 is formed on the whole surface of the semiconductor substrate 100 including the buried bit line 180 and the dummy buried bit line 190. An interlayer insulating layer 210 and a hard mask layer 220 are sequentially formed on the spacer insulating layer 200. The spacer insulating layer may include a nitride layer.

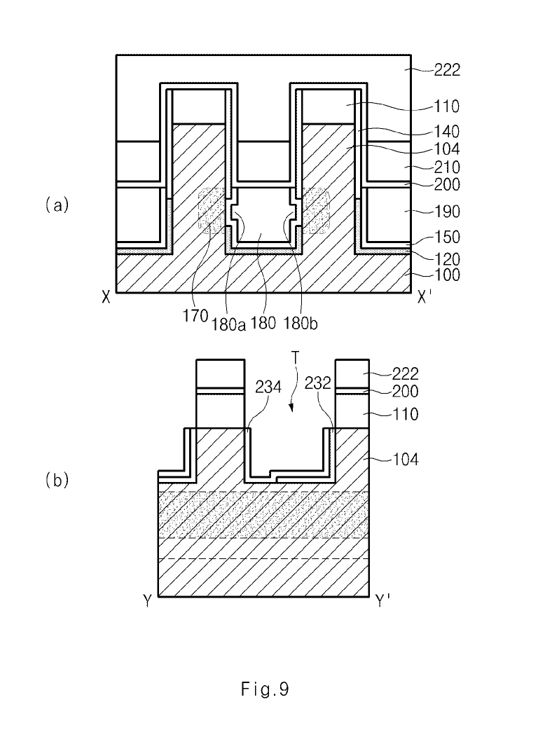

Referring to FIG. 9, a photoresist pattern (not shown) defining a vertical gate region is formed on the hard mask layer 220 and the hard mask layer 220 is etched using the photoresist pattern as an etching mask to form a hard mask pattern 222.

Next, the space insulating layer 200, the hard mask pattern 110 and the pillars 102a and 102b are etched using the hard mask pattern 222 as an etching mask to form trenches T. The trench T divides an upper portion of each line type pillar 102a and 102b to form an island type pillar, for example, a square type pillars 104.

A first gate oxide layer 232 is formed on a surface of the semiconductor substrate 100 exposed by the trench T. A portion of the first gate oxide layer 232 formed on one side of the pillar 104 is removed using a mask which exposes one side of the pillar 104.

Next, a second gate oxide layer 234 is formed on the remaining first gate oxide layer 232 and on a portion of the surface of the semiconductor substrate 100 from which the first gate oxide layer 232 was removed. Accordingly, a thick gate oxide layer including stacked first gate oxide layer 232 and second gate oxide layer 234 is formed on the one side of the pillar 104 and a thin gate oxide layer including only the second gate oxide layer 234 is formed on an opposite sidewall of the pillar 104.

The second gate oxide layer 234 is formed to a thickness sufficient to form a channel in the pillar 104 when a gate voltage is applied. The first gate oxide layer 232 is formed to be thick enough that, when combined with the second gate oxide layer 234, a channel is not formed in pillar 104 when a gate voltage is applied.

For example, the first gate oxide layer 232 is formed to a thickness of 20 to 95 Å and the second gate oxide layer 234 is formed to a thickness of 55 to 60 Å.

The gate oxide layer with different thicknesses is applied to alternate sides of the two adjacent pillars 12 and 14 as illustrated in FIG. 3.

Referring to FIG. 10, a conduction layer for a gate (not shown) is formed on the second gate oxide layer 234 and is etched to form vertical gates 240 and 250 at both sides of the pillar 104. The vertical gates 240 and 250 are running across the buried bit line 180 and the dummy buried bit line 190. The conduction layer for a gate may include a metal layer. The metal layer may include tungsten.

Next, an interlayer insulating layer (not shown) is formed on the whole surface of the semiconductor substrate 100 including the vertical gates 240 and 250. Processes of manufacturing a conventional vertical semiconductor device may be applied to the following process of manufacturing the vertical semiconductor device according to the exemplary embodiment of the present invention.

The above embodiment of the present invention is illustrative and not limitative. Various alternatives and equivalents are possible. The invention is not limited by the embodiment described herein. Nor is the invention limited to any specific type of semiconductor device. Other additions, subtractions, or modifications are obvious in view of the present disclosure and are intended to fall within the scope of the appended claims.

What is claimed is:

1. A vertical semiconductor device, comprising:
a first pillar and a second pillar;
a first bit line contact formed at a lower portion of a first sidewall of the first pillar;
a second bit line contact formed at a lower portion of a first sidewall of the second pillar which faces the first sidewall of the first pillar;
a bit line commonly connected to the first bit line contact and the second bit line contact;
a first gate formed over a second sidewall of the first pillar and over the second sidewall of the second pillar; and
a second gate formed over a third sidewall of the first pillar and over a third sidewall of the second pillar,
wherein the first and second gates extend cross the bit line, respectively.

2. The vertical semiconductor device of claim 1, further comprising a gate oxide layer formed to have different thicknesses on the both sides of the first pillar and the second pillar.

3. The vertical semiconductor device of claim 1, further comprising:
a first gate oxide layer formed between the second sidewall of the first pillar and the first gate; and
a second gate oxide layer formed between the third sidewall of the first pillar and the second gate,
wherein the first gate oxide layer has a thickness sufficient to enable a channel to be formed in the first pillar under the first gate oxide layer, and
wherein the second gate oxide layer has a thickness that is insufficient to form a channel in the first pillar under the second gate oxide layer.

4. The vertical semiconductor device of claim 1, further comprising:
a third gate oxide layer formed between the second sidewall of the second pillar and the first gate; and
a fourth gate oxide layer formed between the third sidewall of the second pillar and the second gate,
wherein the third gate oxide layer has a thickness insufficient to form a channel in the second pillar under the third gate oxide layer, and
wherein the fourth gate oxide layer has a thickness sufficient to enable a channel be formed in the second pillar under the fourth gate oxide layer.

5. The vertical semiconductor device of claim 1, further comprising a first dummy bit line formed over a fourth sidewall of the first pillar and a second dummy bit line formed over a fourth sidewall of the second pillar,
wherein each of the first and the second dummy bit lines is parallel to the bit line.

6. A vertical semiconductor device, comprising:
a first pillar adjacent to a second pillar;
a gate shared with the first pillar and the second pillar; and
a bit line commonly coupled to the first pillar and the second pillar and formed between the first pillar and the second pillar,
wherein the bit line crosses the gate.

7. The vertical semiconductor device of claim 6, further comprising bit line contacts formed on both sidewalls of the bit line and connected to bit line junction regions at lower portions of the first pillar and the second pillar.

8. The vertical semiconductor device of claim 6, wherein the gate includes:
a first gate formed on one sides of the first pillar and the second pillar; and
a second gate formed on the other sides of the first pillar and the second pillar parallel to the first gate.

9. The vertical semiconductor device of claim 8, further comprising a gate oxide layer formed to have different thicknesses on both sides of the first pillar and the second pillar.

10. The vertical semiconductor device of claim 9, wherein the gate oxide layer is formed so that a portion of the gate oxide layer between the first gate and the second pillar has a thicker thickness than a portion of the gate oxide layer between the first gate and the first pillar.

11. The vertical semiconductor device of claim 9, wherein the gate oxide layer is formed so that a portion of the gate oxide layer between the second gate and the first pillar has a thicker thickness than a portion of the gate oxide layer between the second gate and the second pillar.

12. The vertical semiconductor device of claim 6, further comprising dummy bit lines formed on outer sidewalls of the first pillar and the second pillar parallel to the bit line.

13. A method of manufacturing a vertical semiconductor device, comprising:
forming a first pillar and a second pillar adjacent to the first pillar by etching a semiconductor substrate;
forming a first gate coupled to the first pillar;
forming a second gate coupled to the second pillar, the second gate being in parallel to the first gate; and
forming a bit line commonly coupled to the first pillar and the second pillar and formed between the first pillar and the second pillar,
wherein the bit line crosses each of the first and the second gates.

14. The method of claim 13, wherein forming a bit line includes:
forming a plurality of line type pillars by etching the semiconductor substrate;
forming a plurality of bit line junction regions in lower portions of sidewalls of the pillars which face each other; and
forming a conduction layer between the facing sidewalls of the pillars to be commonly coupled to the bit line junction regions in the facing sidewalls.

15. The method of claim 14, wherein the forming bit line junction regions includes:
forming an oxide layer over the lower portions of the facing sidewalls;
forming a nitride layer over exposed upper portions of the facing sidewalls above the oxide layer,
partially removing an upper portion of the oxide layer to expose portions of the pillars; and
diffusing impurities into the exposed portions of the pillars.

16. The method of claim 15, further comprising, before the diffusing impurities, forming a diffusion controlling layer configured to control a diffusion depth into the exposed portions of the pillars.

17. The method of claim 13, wherein the forming a gate includes:
forming a first gate oxide layer between the first pillar and the first gate;
is forming a second gate oxide layer between the first pillar and the second gate;
forming a third gate oxide layer between the second pillar and the first gate;
forming a fourth gate oxide layer between the second pillar and the second gate; and
forming a conduction layer over each of the first, the second, the third, and the fourth gate oxide layers,
wherein the first gate oxide layer is different in thickness from a second gate oxide layer formed between the first pillar and the second gate, and
wherein the third gate oxide layer is different in thicknesses from the fourth gate oxide layer.
